(19) United States
(12) Patent Application Publication
(10) Pub. No.: US 2010/0026149 A1
(43) Pub. Date: Feb. 4, 2010

(54) STAGGERED EMBEDDED TYPE CASING

(75) Inventors: Gui-jiao Zhang, Shanghai City (CN); Shou-Jen Yang, Taipei City (TW)

Correspondence Address: J C PATENTS, 4 VENTURE, SUITE 250, IRVINE, CA, 92618, US

(73) Assignee: INVENTEC CORPORATION, Taipei City (TW)

(21) Appl. No.: 12/397,604

(22) Filed: Mar. 4, 2009

(30) Foreign Application Priority Data
Jul. 31, 2008 (CN) 200810129609.3

(51) Int. Cl. H05K 5/00

(52) U.S. Cl. 312/223.2

(57) ABSTRACT

A staggered embedded type casing is provided. The staggered embedded type casing includes a first casing and a second casing combine together to form a casing body. The first casing has a first surface and a first side. The second casing has a second surface and a second side. The first surface and the second surface are coplanar. A plurality of first embedded portions protrudes from the first side of the first casing and extends to the bottom of the second surface. A plurality of second embedded portions protrudes from the second side of the second casing and extends to the bottom of the first surface. The first embedded portions and the second embedded portions are staggered.

### CROSS-REFERENCE TO RELATED APPLICATION

This application claims the priority benefit of China application serial no. 200810129609.3, filed on Jul. 31, 2008. The entirety of the above-mentioned patent application is hereby incorporated by reference herein and made a part of specification.

### BACKGROUND OF THE INVENTION

1. Field of the Invention

The present invention relates generally to a casing, and more particularly, to a staggered embedded type casing.

2. Description of Related Art

A cover of a computer server is usually divided into two parts, i.e. front cover and rear cover. During the maintenance for replacing components, the front cover and the rear cover must be disassembled first. In the kind of design, the electromagnetic wave easily transmits through a slot between the front cover and the rear cover and goes into the interior of a casing, or leaks from an internal electrical device in the casing when the slot is too wide or bad quality of assembly is happened. Hence, the task of improving the interference of electromagnetic wave and the leakage of the electromagnetic wave is deemed an outstanding problem to overcome.

In addition, the front cover is disposed on the top of a hard disk frame while the rear cover is disposed in the rear of the front cover. When the size of the hard disk frame is 2.5 inches, the length of the front cover is equal to that of the hard disk frame, however, when the size of the hard disk frame is 3.5 inches, the length of the front cover is smaller than that of the hard disk frame. Accordingly, in the conventional manner, the different size between the hard disk frame and the front cover would be complemented by adding another independent cover between the front cover and the rear cover, but causing the rear cover has two parts with different sizes and failing to form an integrated casing. Therefore, lengthy assembly steps and time are spent.

### SUMMARY OF THE INVENTION

The present invention is directed to a staggered embedded type casing for preventing interference of electromagnetic wave or leakage of electromagnetic wave.

In the present invention, a staggered embedded type casing is provided. The staggered embedded type casing includes a first casing and a second casing combine together to form a casing body. The first casing has a first surface and a first side. The second casing has a second surface and a second side. The first surface and the second surface are coplanar. A plurality of first embedded portions protrudes from the first side of the first casing and extends to the bottom of the second surface. A plurality of second embedded portions protrudes from the second side of the second casing and extends to the bottom of the first surface. The first embedded portions and the second embedded portions are staggered.

According to an embodiment of the present invention, the first embedded portions are parallel and separate a distance to each other to form a plurality of first slots between the first embedded portions. In addition, an opening width of the first slots is substantially equal to a width of the corresponding second embedded portions.

According to an embodiment of the present invention, the second embedded portions are parallel and separate a distance to each other to form a plurality of second slots between the second embedded portions. In addition, an opening width of the second slots is substantially equal to a width of the corresponding first embedded portions.

According to an embodiment of the present invention, a plurality of locking elements penetrates the first casing and the second casing, respectively, so as to lock the first casing and the second casing.

According to an embodiment of the present invention, the second casing has a third surface opposite to the second surface and a thick-enhanced sheet disposed on the third surface and adjacent to the second side. The thick-enhanced sheet has a board and a plurality of connection portions connected between the board and the second side, respectively.

Based on the above, the staggered embedded casing of the present invention can prevent the interference of the electromagnetic wave that transmits through the boundary of the first side and the second side into the interior of the casing, or prevent the leakage of the electromagnetic wave from the internal electrical device in the casing.

In order to make the above and other features and advantages of the present invention more comprehensible, embodiments accompanied with figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 is a schematic view illustrating a staggered embedded casing according to an embodiment of the present invention.

FIG. 2A is a schematic cross-sectional view of the staggered embedded casing depicted in FIG. 1 along I-I line, and FIG. 2B is a schematic cross-sectional view of the staggered embedded casing depicted in FIG. 1 along II-II line.

FIG. 3 is a schematic view of a third surface and two folded sides of a second casing according to an embodiment of the present invention.

FIG. 4 is a schematic view of a casing applying to an electronic module according to the present invention.

### DESCRIPTION OF EMBODIMENTS

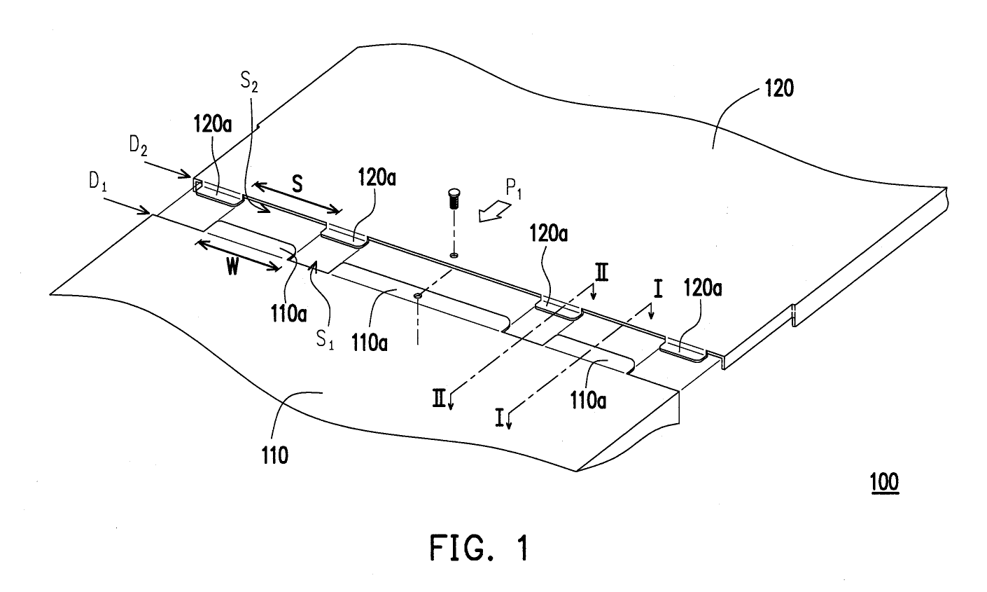

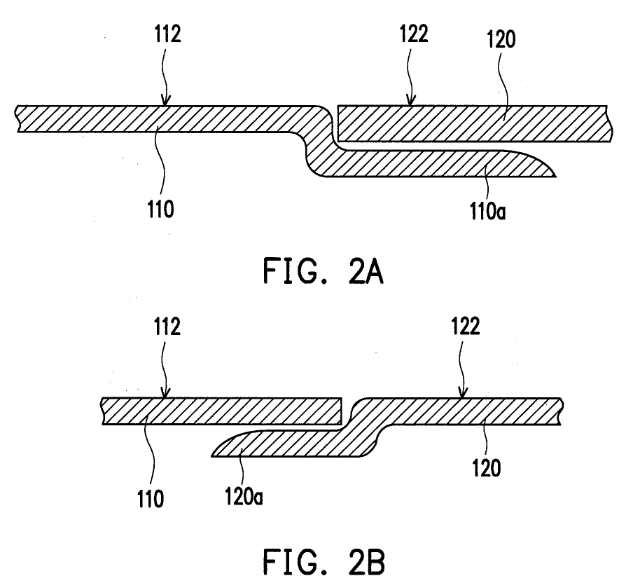

FIG. 1 is a schematic view illustrating a staggered embedded casing according to an embodiment of the present invention. FIG. 2A is a schematic cross-sectional view of the staggered embedded casing depicted in FIG. 1 along I-I line, and FIG. 2B is a schematic cross-sectional view of the staggered embedded casing depicted in FIG. 1 along II-II line.

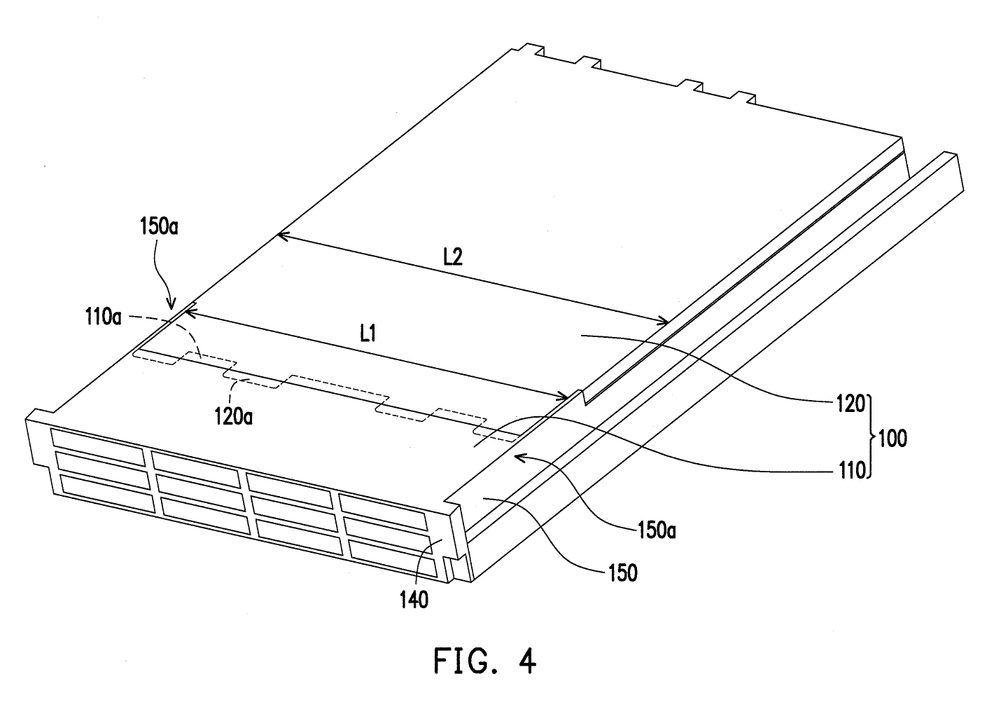

Referring to FIGS. 1 and 4 first, a staggered embedded casing 100 at least includes a first casing 110 and a second casing 120. The first casing 110 and the second casing 120 are connected and combine to form a casing body, such as top cover, side cover, front cover, rear cover or a cover composed of the above two kinds of casing. According to the present embodiment, the first casing 110 serves as a front top cover disposed on the top of a hard disk frame 140, and the second casing 120 serves as a rear cover directly connected in the rear of the first casing 110. In the present embodiment, the first casing 110 serves as a top cover mounted on the hard disk frame 140 and is integrally formed with the hard disk frame 140. The hard disk frame 140 is fixed in the front of a server box 150 and the length of the hard disk frame 140 have a different size according the size of the hard disk, but the length of the first casing is still constant. When the size of the hard disk frame 140 is 2.5 inches, the length of the first casing 110 is equal to that of 2.5 inches hard disk frame 140, however, when the size of the hard disk frame 140 is 3.5 inches, the length of the first casing 110 is smaller than that of 3.5 inches hard disk frame, same as that of 2.5 inches hard disk frame. In the present invention, the front portion of the second casing 120 has a first size L1, which covers the rear portion of the hard disk frame 140 completely, and the rear portion of the second casing 120 has a second size L2, which is equal to the size of original rear cover. Therefore, the second casing 120 of the present invention can be assembled integrally without adding another independent cover.

Referring to FIG. 1, the first casing has a first surface 112 (for example: top surface) and a first side D1. The second casing 120 has a second surface 122 (for example: top surface) and a second side D2. As indicated in FIGS. 2A and 2B, the first surface 112 and the second surface 122 are coplanar. However, in another embodiment (not shown), when the first casing 110 is a top cover and the second casing 120 is a side cover, the first surface 112 of the first casing 110 is arranged vertically or intersects an angle to the second surface 122 of the second casing. Therefore, the first surface 112 and the second surface are coplanar indicated in the drawing of the present embodiment is not restricted to the present invention.

Afterwards, referring to FIGS. 1 and 2A, a plurality of first embedded portions 110a (for example: protruding tongue) protrudes from the first side D1 of the first casing 110 and extends to the bottom of the second surface 122. The thickness of a front end of the first embedded portions 110a is smaller that of the first casing 110 so as to insert into the second casing 120. The first embedded portions 110a are parallel along the first side D1 and separate a distance to each other to form a plurality of first slots S1 between the first embedded portions 110a.

In addition, referring to FIGS. 1 and 2B, a plurality of second embedded portions 120a (for example: protruding tongue) protrudes from the second side D2 of the second casing 120 and extends to the bottom of the first surface 112. The thickness of a front end of the second embedded portions 120a is smaller that of the second casing 120 so as to insert into the first casing 110. The second embedded portions 120a are parallel along the second side D2 and separate a distance to each other to form a plurality of second slots S2 between the second embedded portions 120a.

In details, when the second casing 120 moves along a assembly direction P1 and combines with the first casing 110 to form a casing body, the first embedded portions 110a and the second embedded portions 120a are staggered. The first embedded portions 110a insert into corresponding second slots S2 and the second embedded portions 120a insert into corresponding first slots S1 so as to prevent the interference of an electromagnetic wave that transmits through the boundary of the first side D1 and the second side D2 into the interior of the casing 100.

As indicated in FIG. 1, an opening width of the first slots S1 is substantially equal to a width of the corresponding second embedded portions 120a in order to prevent the interference of electromagnetic wave that transmits into the interior of the casing 100 or leaks from the interior of the casing 100. In addition, an opening width S of the second slots S2 is substantially equal to a width W of the corresponding first embedded portions 110a so as to prevent from the electromagnetic wave transmitting into the interior of the casing 100 or leaking from the interior of the casing 100.

In addition, when the second casing 120 and the first casing 110 are combined to form a casing body, a hole of the first casing 110 overlaps a hole of the second casing 120 to form a fixing hole, through which a fastener (for example: a screw) is mounted on the casing body. In the present embodiment, the hole of the first casing 110 is disposed, for example, on the first embedded portions 110a. The number of the screws is more than one to enhance the locking force. The screw minimizes a tolerance of a gap between the first casing 110 and the second casing 120. This is to say, the first casing 110 and the second casing 120 tightly combine to avoid the electromagnetic wave transmitting through the gap smoothly.

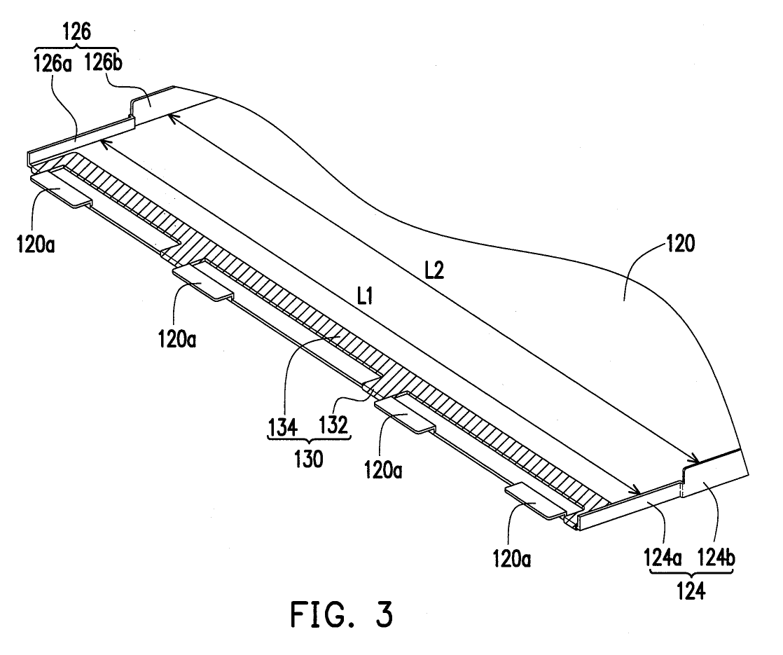

Next, referring to FIG. 3 that indicates a schematic view of a third surface and two folded sides of the second casing depicted in FIG. 1. A thick-enhanced sheet 130 is disposed on a third surface (for example: bottom surface) of the second casing 120 adjacent to the second side D2 in order to improve the strength of the second casing 120. In details, the thick-enhanced sheet 130 is made by use of a remaining material of the second casing 120, i.e. a board 134 (for example: long stripe) and a plurality of connecting portions 132 (connected between the board 134 and the second side D2) when the second casing 120 is completely fabricated with a plurality of second embedded portions 120a, and then the thick-enhanced sheet 130 is folded on the third surface to increase the thickness of the second casing 120. Therefore, the thickness of the edge area of the second casing 120 adjacent to the second side D2 is larger than that of non-edge area to improve the strength of the second casing 120.

In addition, referring to FIG. 3, the second casing further has a first folded side 124 and a second folded side 126 vertical to the second side D2. A first segment (near the second side D2) 124a of the first folded side 124 is parallel to a first segment 126a (near the second side D2) of the second folded side 126 and space a first size L1 apart. A second segment (far from the second side D2) 124b of the first folded side 124 is parallel to a second segment 126b (far from the second side D2) of the second folded side 126 and space a second size L2 apart. The first size L1 is smaller than the second size L2, that is, L1<L2. Thereby, the second casing 120 has multiple sizes between the first folded side 124 and the second folded side 126. Since the length of the hard disk frame 140 has different size according to different hard disk's size, and the size of the first casing 110 on the top of the hard disk frame 140 is still constant, the first segment 124a of the first folded side 124 and the first segment 126a of the second folded side 126 shrink inward to be the first size L1 can make the front end of the second casing 120 cover the hard disk frame 140 and embed into two opposite sidewalls 150a of a server box 150. The second segment 124b of the first folded side 124 and the second segment 126b of the second folded side 126 still retain a second size L2 and thereby expose over the two opposite sidewalls 150a of the server box 150. Therefore, the second casing 120 and the opposite sidewalls 150a of the server box 150 can insert to each other and fix together.

As depicted in FIG. 4, since the second casing 120 has different sizes so that a user can integrally assemble the second casing 120 on the server box 150 having the hard disk frame 140. In comparison with the conventional manner to mount two independent rear covers on a electronic module respectively, the assembly steps and time are simplified by use of the second casing 120 of the present invention.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A staggered embedded type casing, comprising:
a first casing and a second casing connected to each other, wherein the first casing has a first surface and a first side, the second casing has a second surface and a second side, the first surface and the second surface are coplanar, a plurality of first embedded portions protrudes from the first side of the first casing and extends to the bottom of the second surface, a plurality of second embedded portions protrudes from the second side of the second casing and extends to the bottom of the first surface, the first embedded portions and the second embedded portions are staggered.

2. The staggered embedded type casing as claimed in claim 1, wherein the first embedded portions are parallel and separate a distance to each other to form a plurality of first slots between the first embedded portions.

3. The staggered embedded type casing as claimed in claim 2, wherein an opening width of the first slots is substantially equal to a width of the corresponding second embedded portions.

4. The staggered embedded type casing as claimed in claim 1, wherein the second embedded portions are parallel and separate a distance to each other to form a plurality of second slots between the second embedded portions.

5. The staggered embedded type casing as claimed in claim 4, wherein an opening width of the second slots is substantially equal to a width of the corresponding first embedded portions.

6. The staggered embedded type casing as claimed in claim 1, wherein a plurality of locking elements penetrates the first casing and the second casing respectively to lock the first casing and the second casing.

7. The staggered embedded type casing as claimed in claim 1, wherein the second casing has a third surface opposite to the second surface and a thick-enhanced sheet disposed on the third surface and adjacent to the second side. The thick-enhanced sheet has a board and a plurality of connection portions connected between the board and the second side respectively.

8. The staggered embedded type casing as claimed in claim 1, wherein the thickness of a front end of the first embedded portions is smaller that of the first casing.

9. The staggered embedded type casing as claimed in claim 1, wherein the thickness of a front end of the second embedded portions is smaller that of the second casing.

10. The staggered embedded type casing as claimed in claim 1, further comprising:
a server box having two opposite sidewalls parallel to each other; and
a hard disk frame disposed at a front portion of the server box,
wherein the first casing serve as a top wall of the hard disk frame, and the second casing overlying a rear portion of the server box.

11. The staggered embedded type casing as claimed in claim 10, wherein the second casing further comprising a first folded side and a second folded side vertical to the second side, and both the first folded side and the second folded side including a first segment and a second segment, the first segment of the first folded side and the first segment of the second folded side shrink inward and embed into the two opposite sidewalls, and the second segment of the first folded side and the second segment of the second folded side expose over the two opposite sidewalls of the server box.
